(19) United States
(12) Patent Application Publication
(10) Pub. No.: US 2026/0066239 A1
(43) Pub. Date: Mar. 5, 2026

(54) PLASMA SOURCE WITH INTEGRATED CHAMBER LINER

(71) Applicant: Applied Materials, Inc., Santa Clara, CA (US)

(72) Inventors: SRIKANTHA RAJU, Bangalore (IN); KIRAN HONNAVAR, Bangalore (IN); LARRY D. ELIZAGA, Tracy, CA (US); JAMES CARDUCCI, Sunnyvale, CA (US); SILVERST RODRIGUES, San Jose, CA (US); JUSTIN RAMOS, Santa Clara, CA (US); PAUL COUTINHO, Sunnyvale, CA (US)

(21) Appl. No.: 18/823,431

(22) Filed: Sep. 3, 2024

(51) Int. Cl. H01J 37/32

(52) U.S. Cl. CPC H01J 37/32495; H01J 37/32522; H01J 2237/2001

(57) ABSTRACT

Embodiments described herein relate to an apparatus that includes a source assembly with a first surface and a second surface opposite from the first surface. In an embodiment, a liner is coupled to the first surface of the source assembly. In an embodiment, the liner includes a first liner over at least a portion of the first surface, and a second liner that extends away from the first liner. In an embodiment, the second liner includes a ring shape, and the first liner and the second liner are a monolithic structure.

### BACKGROUND

### 1) Field

Embodiments of the present disclosure pertain to the field of plasma chambers with a source assembly and a chamber liner that are integrated as a single component.

### 2) Description of Related Art

In semiconductor manufacturing, plasma chambers are used to implement various processes, such as etching, deposition, plasma treatment, etc. Plasma chambers include a source assembly that is used to couple power (e.g., RF power, microwave power, etc.) into the chamber. The source assembly may be part of a lid that seals the chamber. A chamber liner is also provided within the chamber. The chamber liner is traditionally provided as a discrete component from the source assembly. This configuration was chosen as a standard approach in order to allow for easier removal of the chamber lid (which includes the source assembly) during maintenance. For example, since the chamber liner extends vertically into the chamber volume, it is not possible to remove the chamber liner along with the source assembly with a hinged motion.

However, providing the chamber liner and the source assembly as discrete components results in the two components needing their own heating and cooling systems. Accordingly, the two components may have temperature non-uniformities that can negatively impact the processing within the chamber. That is, a temperature of a surface of the source assembly that is exposed to the processing environment may be different than a temperature of a surface of the chamber liner that is exposed to the processing environment.

### SUMMARY

Embodiments described herein relate to an apparatus that includes a source assembly with a first surface and a second surface opposite from the first surface. In an embodiment, a liner is coupled to the first surface of the source assembly. In an embodiment, the liner includes a first liner over at least a portion of the first surface, and a second liner that extends away from the first liner. In an embodiment, the second liner includes a ring shape, and the first liner and the second liner are a monolithic structure.

Embodiments described herein relate to an apparatus that includes a chamber with an opening. In an embodiment, a lid assembly is configured to seal the opening of the chamber. In an embodiment, the lid assembly includes a source assembly, and a liner. In an embodiment, the liner covers a surface of the source assembly and an interior sidewall of the chamber when the lid assembly seals the opening of the chamber.

Embodiments described herein relate to an apparatus that includes a metallic source for a plasma chamber, and a liner coupled to the metallic source. In an embodiment, the liner includes a plate portion over the metallic source, and a ring portion around a perimeter of the plate portion. In an embodiment, the ring portion extends from the plate portion away from the metallic source.

### BRIEF DESCRIPTION OF THE DRAWINGS

FIG. 1 is a cross-sectional illustrations of a plasma chamber with a source assembly and a chamber liner that are discrete components, in accordance with an embodiment.

FIG. 2A is a cross-sectional illustration of a plasma chamber with a source assembly with an integrated chamber liner, in accordance with an embodiment.

FIG. 2B is a cross-sectional illustration of a plasma chamber with a source assembly with an integrated chamber liner that is being vertically placed on the chamber, in accordance with an embodiment.

FIG. 3A is a plan view illustration of the source assembly, in accordance with an embodiment.

FIG. 3B is a plan view illustration of the source assembly coupled to a guide for rotating the source assembly away from the chamber opening, in accordance with an embodiment.

FIG. 4A is a plan view illustration of a plasma chamber with a guide coupled to the source assembly in a position where the chamber opening is exposed, in accordance with an embodiment.

FIG. 4B is a plan view illustration of a plasma chamber with a guide coupled to the source assembly in a position where the chamber opening is covered, in accordance with an embodiment.

FIG. 5 is a perspective view illustration of a plasma chamber with a hoist assembly for vertically lifting the source assembly, in accordance with an embodiment.

FIG. 6 is a flow diagram depicting a process for removing a source assembly from the chamber with a vertical lifting motion, in accordance with an embodiment.

FIG. 7 illustrates a block diagram of an exemplary computer system of a processing tool, in accordance with an embodiment of the present disclosure.

### DETAILED DESCRIPTION

Plasma chambers with a source assembly and a chamber liner that are integrated as a single component are disclosed herein, in accordance with various embodiments. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, existing plasma tools typically include a source assembly that has a source liner that is discrete from the chamber liner. The chamber liner protects sidewalls of the chamber during processing. The use of discrete components for the source liner and the chamber liner results in the need for different temperature control systems. Accordingly, temperature differences may be present between the source liner and the chamber liner. This can lead to processing non-uniformities.

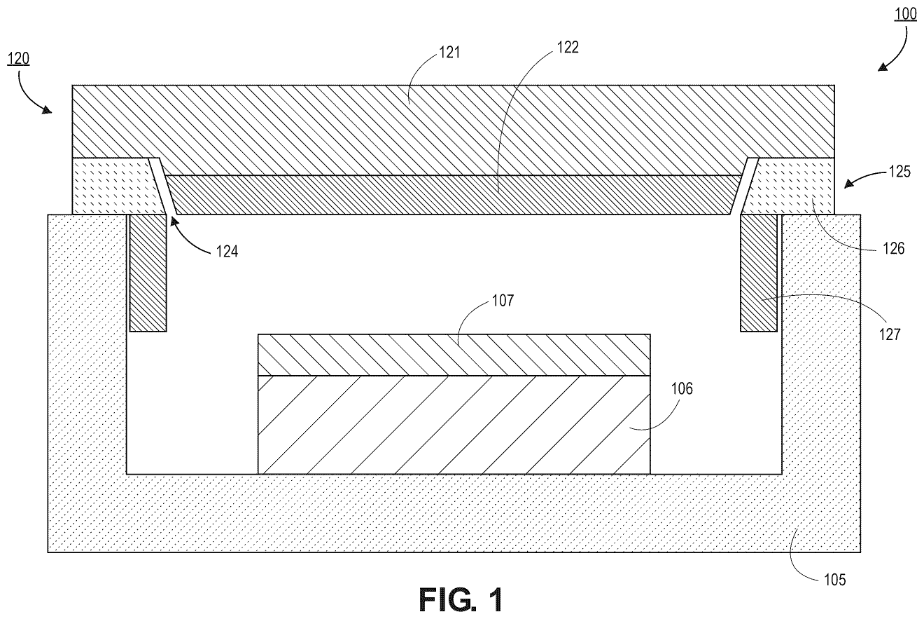

An example of such a plasma tool 100 is shown in FIG. 1. As shown, a chamber 105 may include a cathode assembly 106 and a chuck 107 over the cathode assembly 106. The chuck 107 may be an electrostatic chuck (ESC) in some embodiments. A liner assembly 125 may be provided over the chamber 105. The liner assembly 125 may comprise a metallic ring 126 and a chamber liner 127 that extends into the chamber 105. The chamber liner 127 may comprise a polysilicon material or other material compatible with the plasma environment within the chamber 105. The liner assembly 125 may comprise a temperature control system. For example, heating elements (e.g., resistive heating elements) or cooling systems (e.g., coolant channels) may be provided in the metallic ring 126 and/or the chamber liner 127.

The plasma tool 100 may also comprise a source assembly 120. The source assembly 120 may comprise a metallic portion 121 and a source liner 122. The source liner 122 may comprise polysilicon or the like. The source liner 122 and the chamber liner 127 may comprise the same materials in some embodiments. The source assembly 120 may also comprise a temperature control system. For example, heating elements (e.g., resistive heating elements) or cooling systems (e.g., coolant channels) may be provided in the metallic portion 121.

As shown, a gap 124 is provided between the chamber liner 127 of the liner assembly 125 and the source liner 122 of the source assembly 120. In order to prevent plasma ignition in the gap 124, an RF gasket or the like (not shown) may be provided in the gap 124 to seal off at least a portion of the gap 124. Since there are two different temperature control systems in the plasma tool 100, the temperature uniformity along the plasma exposed regions of the chamber liner 127 and the source liner 122 may not be uniform. This can lead to difficulties in controlling process uniformity across a wafer on the chuck 107 (e.g., etch uniformity, deposition uniformity, etc.).

Accordingly, embodiments disclosed herein may include the use of a lid that integrates both the liner of the source assembly and the chamber liner into a single component. As such, a single temperature control system can be used to minimize (or eliminate) a temperature gradient across the plasma exposed regions so that abrupt changes in temperature are eliminated from around the process volume. Such a configuration allows for improvements to the plasma distribution within the chamber and improves process uniformity.

In embodiments disclosed herein, the lid assembly that integrates the source liner and the chamber liner into a single structure uses a different architecture for attaching and/or removing the lid assembly compared to existing solutions. For example, existing solutions lift the source assembly with a hinged approach. Since the lid assembly in accordance with embodiments disclosed herein has a protruding ring that extends into the chamber (i.e., the chamber liner portion), a hinged approach is not feasible. Accordingly, embodiments disclosed herein include an approach that includes a swiveling guide arm that rotates the lid assembly away from the chamber for servicing after the chamber liner is lifted vertically out of the chamber.

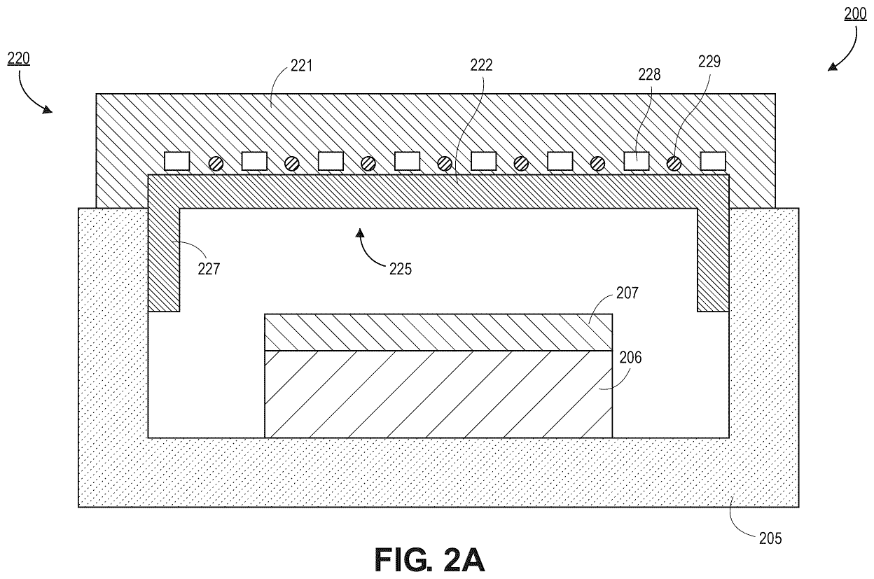

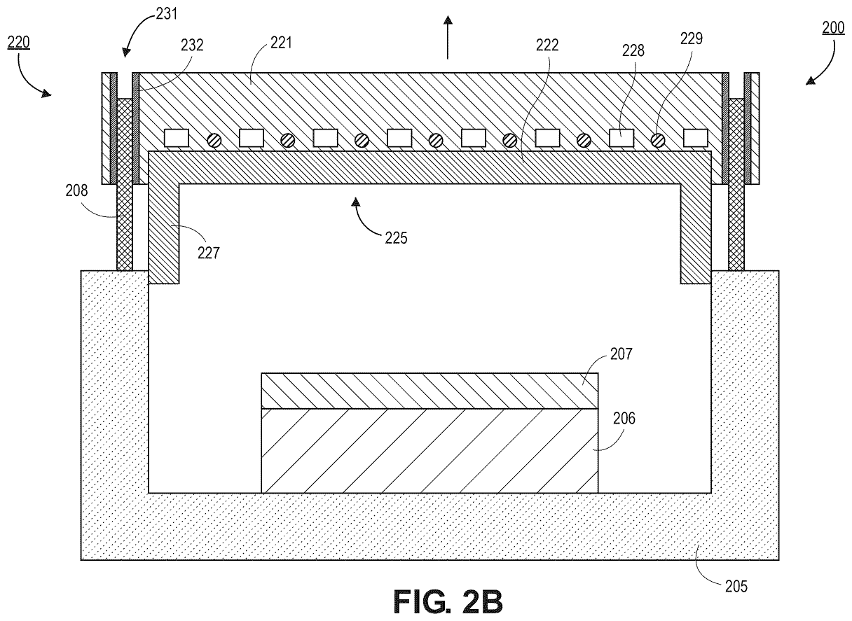

Referring now to FIG. 2A, a cross-sectional illustration of a plasma tool 200 is shown, in accordance with an embodiment. In an embodiment, the plasma tool 200 may comprise a chamber 205. The chamber 205 may include a cathode assembly 206 and a chuck 207 over the cathode assembly 206. The chuck 207 may be an ESC in some embodiments. In an embodiment, the chamber 205 has an opening that is covered by a lid assembly 220.

In an embodiment, the lid assembly 220 may comprise a source assembly 221 and a liner 225. The liner 225 may include a source liner 222 that covers a bottom of the source assembly 221 and a chamber liner 227 that covers an interior sidewall of the chamber 205. The chamber liner 227 may be a ring (or a partial ring) that extends away from the source assembly 221 to line walls of the chamber 205. That is, the chamber liner 227 extends into the chamber 205. The source liner 222 may be a plate that covers a bottom of the source assembly 221. The source liner 222 and the chamber liner 227 may be a monolithic structure. In some embodiments, there may not be a seam between the source liner 222 and the chamber liner 227. In an embodiment, the source liner 222 and the chamber liner 227 may comprise polysilicon or any other material compatible with the plasma environment within the chamber 205.

In an embodiment, the source assembly 221 may comprise a temperature control system. The temperature control system may include heating elements 229 (e.g., resistive heaters, etc.) and/or cooling channels 228. In some embodiments, the temperature control system may be a single zone temperature controller or a multi-zone temperature controller. For example, the temperature controller may comprise an inner temperature control system and an outer temperature control system. Since the source liner 222 and the chamber liner 227 are provided as a single component, the temperature control system allows for a single system to control the temperature of both the source liner 222 and the chamber liner 227. As such, temperature gradients between the source liner 222 and the chamber liner 227 are reduced or eliminated. This allows for more uniform processing outcomes on the wafer within the chamber 205.

Since the chamber liner 227 extends into the chamber 205, removal of the lid assembly 220 with a hinged solution may not be feasible. That is, the ring shape of the chamber liner 227 prevents the lid assembly 220 from being rotated up and out of the chamber 205. Accordingly, embodiments include a vertical lifting process for removing and/or replacing the lid assembly 220.

Referring now to FIG. 2B, a cross-sectional illustration of the plasma tool 200 during removal of the lid assembly 220 is shown, in accordance with an embodiment. As indicated by the arrow, the lid assembly 220 may be lifted vertically up from the chamber 205. In some embodiments, pins 208 may be coupled to the chamber 205 in order to provide alignment between the lid assembly 220 and the chamber 205. For example, holes 231 for receiving the pins 208 may pass through the source assembly 221. The holes 231 may be lined by a bushing 232 or the like in order to engage the pins 208 with a tight tolerance to prevent tilting and/or shifting. High precision alignment is desirable since the chamber liner 227 may be a fragile component that is susceptible to damage if the chamber liner 227 impacts the chamber 205. In an embodiment, the lid assembly 220 may be lifted and/or lowered by a hoist or the like, as will be described in greater detail herein.

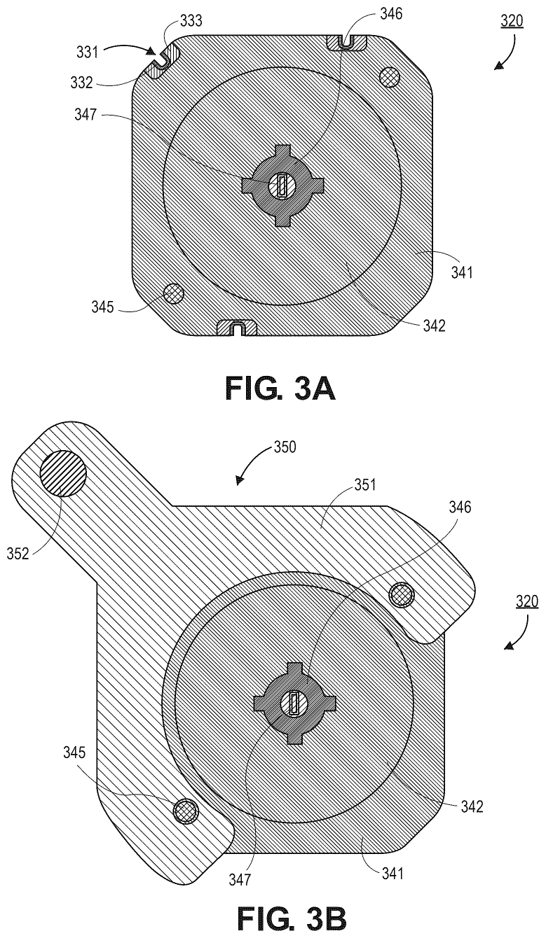

Referring now to FIG. 3A, a plan view illustration of a lid assembly 320 is shown, in accordance with an embodiment. In an embodiment, the lid assembly 320 may comprise a plate 341 with an extension 342 that extends up from the plate 341. While illustrated simply as a plate 341 and a cylindrical block for the extension 342 in FIG. 3A, it is to be appreciated that the lid assembly 320 may have a more complex structure that comprises many different components, systems, housings, and/or the like. For example, the lid assembly 320 may comprise heating elements, cooling channels, gas distribution paths, electrical paths (e.g., for RF power or the like), and/or the like.

In an embodiment, a fixture 346 with a connector 347 is provided on the extension 342. The fixture 346 may be configured to couple with a hoist to vertically displace the lid assembly 320. The fixture 346 may be a mechanically robust structure (such as a metallic material) that is securely affixed to the lid assembly 320 to allow for lifting the lid assembly 320. The connector 347 may comprise a hook, a loop, a socket, a slot, or any other structure suitable for releasably coupling to a hoist (not shown in FIG. 3A).

In an embodiment, pins 345 may extend up from the plate 341 adjacent to the extension 342. Though, the pins 345 may also be provided on any suitable portion of the lid assembly 320. The pins 345 may be used to couple the lid assembly 320 to a guide (not shown in FIG. 3A) that is used to rotate the lid assembly 320 away from the chamber. As will be described in greater detail herein, the guide is configured to engage the pins 345 after the lid assembly 320 is lifted up from the chamber. Thereafter, the guide can rotate so that the lid assembly 320 is cleared from the chamber opening in order to allow for maintenance of the chamber.

In an embodiment, the plate 341 may also comprise a plurality of guide holes 331. The guide holes 331 may be open to the edge of the plate 341. Though, in other embodiments, the guide holes 331 may be set away from the edge of the plate 341. For example, holes 231 are set away from the edge in FIG. 2B. The guide holes 331 may be lined with a bushing 332 in some embodiments. The bushing 332 may allow for improved alignment with the chamber (not shown). The bushing 332 may be a complete cylinder, or the bushing 332 may have an opening at the edge of the plate 341 (as shown in FIG. 3A). In an embodiment, a strike plate 333 may surround the guide holes 331.

Referring now to FIG. 3B, a plan view illustration of a lid assembly 320 that is coupled to a guide 350 is shown, in accordance with an embodiment. In an embodiment, the guide 350 may comprise an attachment arm 351 that is coupled to the pins 345. For example, the pins 345 may pass through holes in the attachment arm 351. In some embodiments, a strike plate or the like may be provided around the holes. This allows for the guide 350 to be mechanically coupled to the lid assembly 320 without directly contacting the plate 341 or the extension 342 (which may comprise more fragile components). In an embodiment, the attachment arm 351 may partially surround the lid assembly 320. For example, FIG. 3B shows the attachment arm 351 surrounding about half of the perimeter of the extension 342. The opening of the attachment arm 351 allows for the lid assembly 320 to remain suspended by the hoist (not shown in FIG. 3B) as the lid assembly 320 is engaged with the attachment arm 351.

In an embodiment, the attachment arm 351 may be coupled to a pivot point 352. The guide 350 may rotate about the pivot point 352 in order to move the lid assembly 320 away from the chamber (not shown) so that the lid assembly 320 can undergo maintenance or the like. The guide 350 may not support a substantial amount of the weight of the lid assembly 320. Instead, the lid assembly 320 may be supported by the hoist. This allows for the pins 345 to be inserted up through the bottom of holes in the attachment arm 351. As the guide 350 rotates, the attachment arm 351 moves the lid assembly 320 through contact with the pins 345.

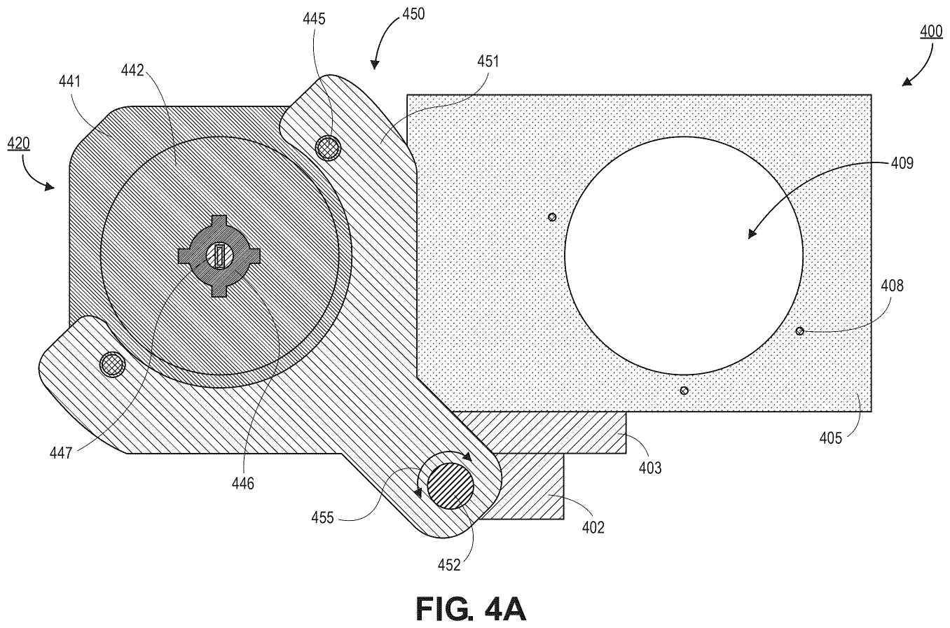

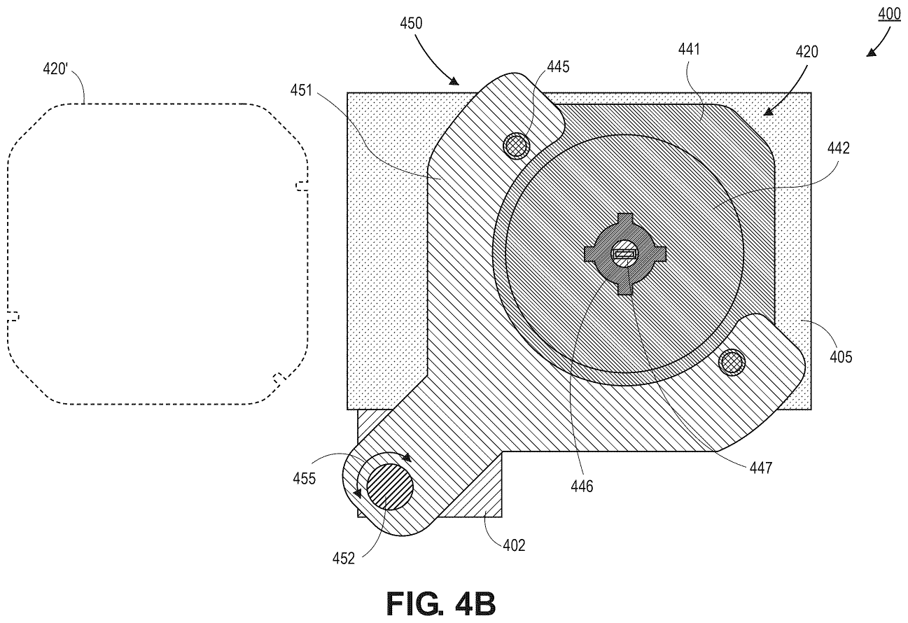

Referring now to FIG. 4A a plan view illustration of a plasma tool 400 is shown, in accordance with an embodiment. In an embodiment, the plasma tool 400 may comprise a chamber 405. The chamber 405 may have an opening 409. In an embodiment, a plurality of pins 408 may be provided around the opening 409. The plurality of pins 408 may be used to align the lid assembly 420 to the opening 409.

As shown, a guide 450 may be coupled to the chamber 405. In an embodiment, the guide 450 may include a mounting plate 402 that is coupled to a shear plate 403. The shear plate 403 may be coupled to an outer sidewall of the chamber 405. In an embodiment, the guide 450 may rotate 455 about the pivot point 452. The guide 450 may be coupled to the lid assembly 420 by pins 445 that pass through holes in the attachment arm 451.

In an embodiment, the lid assembly 420 may be similar to any of the other lid assemblies described in greater detail herein. For example, an extension 442 may extend up from a plate 441. A fixture 446 for securing a connector 447 is provided over the extension 442. The lid assembly 420 may also comprise guide holes that are sized to receive the pins 408 on the chamber 405. The guide holes of the lid assembly 420 are below the attachment arm 451 and are not visible in FIG. 4A. Though, the guide holes may be substantially similar to the guide holes 331 described with respect to FIG. 3A.

In the illustrated embodiment of FIG. 4A, the lid assembly 420 is rotated away from the opening 409 of the chamber 405. While in this position, the chamber 405 is accessible for maintenance, cleaning, and/or the like. When the chamber 405 is brought back online, the guide 450 may be rotated so that the lid assembly 420 is positioned over the opening 409.

Referring now to FIG. 4B, a plan view illustration of the plasma tool 400 after the lid assembly 420 is positioned over the opening 409 is shown, in accordance with an embodiment. In an embodiment, the lid assembly 420 may be rotated by the guide 450 from outside of the chamber 405 (as indicated by dashed line 420′) to above the opening 409. After being positioned over the opening 409, the lid assembly 420 may be lowered onto the chamber 405 to seal the opening 409. In an embodiment, a hoist (not shown) may support the weight of the lid assembly 420 while the lid assembly 420 is engaged with the guide 450. The hoist may be used to lower the lid assembly 420 onto the chamber 405. In an embodiment, the pins 408 of the chamber 405 engage the guide holes of the lid assembly 420 as the lid assembly 420 is lowered onto the chamber 405. The pins 408 and the guide holes provide the proper alignment for the lid assembly 420 so that the liner (not visible in FIG. 4B) can be inserted into the opening 409 without contacting the chamber 405. As such, the liner is protected from damage during the closing and/or opening of the chamber 405. The pins 408 and the guide holes are obscured from view in FIG. 4B by the attachment arm 451.

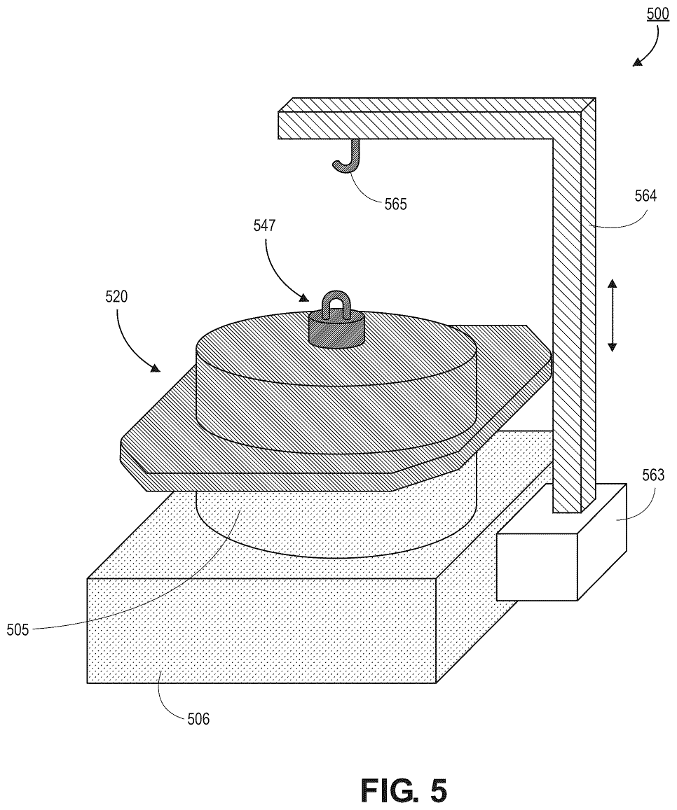

Referring now to FIG. 5, a perspective view illustration of a plasma tool 500 is shown, in accordance with an embodiment. In an embodiment, the plasma tool 500 may comprise a chamber 505 that is provided over an enclosure 506. The enclosure 506 may cover electrical, gas, and/or other utility lines that are provided to the chamber 505. In an embodiment, a lid assembly 520 may be provided over the chamber 505. The lid assembly 520 may be similar to any of the lid assemblies described in greater detail herein. For example, the lid assembly 520 may comprise a source assembly and a liner. The liner may comprise a source liner and a chamber liner. When the lid assembly 520 is coupled to the chamber 505 (e.g., to seal an opening of the chamber 505), the chamber liner may extend into the chamber 505 and cover at least a portion of an interior sidewall of the chamber 505. In an embodiment, the source liner and the chamber liner are a monolithic structure, as described in greater detail herein.

Due to the extension of the chamber liner into the chamber 505, the lid assembly 520 may need to be vertically lifted in order to remove the lid assembly 520. In order to allow for the vertical lift-off, a connector 547 may be mechanically coupled to the lid assembly 520. The connector 547 may be any suitable connector structure that is capable of detachably coupling with a hoist 564. For example, the connector 547 may comprise a loop, a hook, a slot, a socket, or any other suitable connecting structure.

In an embodiment, the hoist 564 may be coupled to a mount 563 that is attached to an external surface of the chamber 505 or the enclosure 506. The hoist 564 may have a vertical member and a cross-beam that extends over the lid assembly 520. A connector 565 may be coupled to the cross-beam. In an embodiment, the connector 565 is configured to detachably couple with the connector 547 of the lid assembly 520. For example, the connector 565 in FIG. 5 is a hook. Though, the connector 565 any include suitable coupling architecture that is compatible with the connector 547 of the lid assembly 520.

In an embodiment, the hoist 564 may be vertically displaceable (as indicated by the double sided arrows). The vertical member of the hoist 564 may be raised or lowered in some embodiments. In other embodiments, the vertical member of the hoist 564 remains substantially stationary in the vertical direction, and the connector 565 is displaced in the vertical direction by a pully system or other lifting mechanism. In some embodiments, the hoist 564 may support substantially all of the weight of the lid assembly 520 when the lid assembly 520 is removed from the chamber 505.

In the illustrated embodiment, the guide arm is omitted for clarity. However, it is to be appreciated that after the lid assembly 520 is vertically lifted up away from the chamber 505, the guide arm may be coupled to the lid assembly 520, as described in greater detail herein. The guide arm may then rotate the lid assembly 520 away from the chamber 505 while the hoist 564 continues to support a majority of the weight of the lid assembly 520. In some embodiments, the hoist 564 may also be rotatable in order to rotate with the guide arm during the opening of the chamber 505.

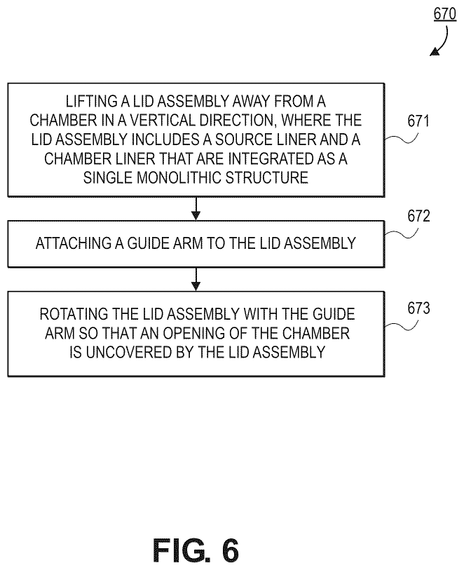

Referring now to FIG. 6, a flow diagram of a process 670 for removing a lid assembly from a chamber with a vertical lifting process is shown, in accordance with an embodiment. In an embodiment, the process 670 may begin with operation 671, which comprises lifting a lid assembly away from a chamber in a vertical direction. In an embodiment, the lid assembly comprises a source liner and a chamber liner that are integrated as a single monolithic structure. The lid assembly may be similar to any of the lid assembly structures described in greater detail herein. In some embodiments, the source liner may be a plate that is provided over a source assembly used to couple RF or microwave energy into the chamber, and the chamber liner is a ring that extends down from the source liner. When the lid assembly is covering an opening of the chamber, the chamber liner may extend into an interior volume of the chamber.

In an embodiment, the lid assembly may be lifted up away from the chamber with a hoist. The hoist may be mechanically coupled to an exterior of the chamber in some embodiments. The hoist may have a connector that is configured to couple with a connector of the lid assembly. The hoist may lift the lid assembly in a substantially vertical direction. The vertical lift-off of the lid assembly allows for the chamber liner to be withdrawn from the interior of the chamber without the chamber liner contacting surfaces of the chamber.

In an embodiment, the process 670 may continue with operation 672, which comprises attaching a guide arm to the lid assembly. In an embodiment, the guide arm may comprise a plurality of holes or slots, and the lid assembly may comprise a corresponding number of pins. The pins may be inserted into the holes or slots of the guide arm in order to mechanically couple the guide arm to the lid assembly. The guide arm may be attached to the lid assembly while the hoist supports a majority of the weight of the lid assembly. In order to couple both the hoist and the guide arm to the lid assembly, the guide arm may partially surround a perimeter of the lid assembly. In an embodiment, the guide arm may be coupled to an exterior of the chamber. The guide arm may be rotatable in order to displace the lid assembly laterally after the lid assembly is coupled to the guide arm.

In an embodiment, the process 670 may continue with operation 673, which comprises rotating the lid assembly with the guide arm so that at least a portion of an opening of the chamber is uncovered by the lid assembly. In an embodiment, the rotation of the lid assembly may be provided about a vertical axis that is outside of the chamber. For example, the axis of rotation may pass through at least a portion of the guide arm. The rotation may also provide movement of the lid assembly that is substantially within a single plane that is substantially orthogonal to the lifting direction. That is, a hoist may vertically lift the lid assembly, and the guide arm may rotate the lid assembly in a horizontal plane that is orthogonal to the vertical lifting direction.

This is in contrast to previous lid assembly removal operations where the lid assembly is removed with a hinged approach (i.e., where the lid assembly is tilted up so that one edge of the lid assembly is raised vertically higher than an opposite edge of the lid assembly). In the vertical lifting and rotating process described in process 670, the bottom surface of the lid assembly may remain substantially parallel within the ground. More generally, a hinged approach may not be compatible with a lid assembly with a liner that combines both the source liner and the chamber liner because the chamber liner would not be able to rotate out of the chamber when a hinged motion is applied to the lid assembly.

It is to be appreciated that the process described in FIG. 6 may also be implemented substantially in reverse in order to place the lid assembly back onto the chamber. For example, the lid assembly may be rotated back over the chamber opening by the guide arm. After the lid assembly is positioned over the opening, the guide arm may be disengaged. The hoist may then lower the lid assembly back onto the chamber. In order to ensure proper alignment of the lid assembly to the chamber, pins provided on the chamber may engage slots and/or holes within the lid assembly. The slots and/or holes may also comprise bushings or the like in order to provide improved alignment accuracy as the lid assembly is coupled to the chamber. Proper alignment of the lid assembly allows for the chamber liner portion of the lid assembly to vertically enter the interior of the chamber without contacting surfaces of the chamber in order to prevent damage to the lid assembly.

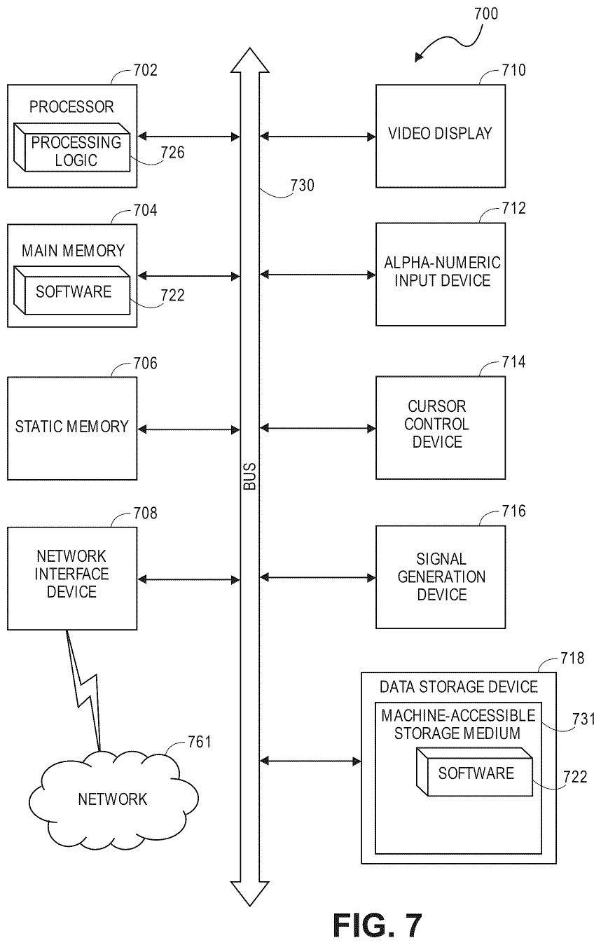

Referring now to FIG. 7, a block diagram of an exemplary computer system 700 of a processing tool is illustrated in accordance with an embodiment. In an embodiment, computer system 700 is coupled to and controls a plasma chamber with a lid assembly that comprises a source assembly and a liner with a monolithic source liner and chamber liner construction.

Computer system 700 may be connected (e.g., networked) to other machines in a Local Area Network (LAN), an intranet, an extranet, or the Internet. Computer system 700 may operate in the capacity of a server or a client machine in a client-server network environment, or as a peer machine in a peer-to-peer (or distributed) network environment. Computer system 700 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 700, the term “machine” shall also be taken to include any collection of machines (e.g., computers) that individually or jointly execute a set (or multiple sets) of instructions to perform any one or more of the methodologies described herein.

Computer system 700 may include a computer program product, or software 722, having a non-transitory machine-readable medium having stored thereon instructions, which may be used to program computer system 700 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 700 includes a system processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

System processor 702 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 702 may also be one or more special-purpose processing devices such as an application specific integrated circuit (ASIC), a field programmable gate array (FPGA), a digital signal system processor (DSP), network system processor, or the like. System processor 702 is configured to execute the processing logic 726 for performing the operations described herein.

The computer system 700 may further include a system network interface device 708 for communicating with other devices or machines. The computer system 700 may also include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium 731 (or more specifically a computer-readable storage medium) on which is stored one or more sets of instructions (e.g., software 722) embodying any one or more of the methodologies or functions described herein. The software 722 may also reside, completely or at least partially, within the main memory 704 and/or within the system processor 702 during execution thereof by the computer system 700, the main memory 704 and the system processor 702 also constituting machine-readable storage media. The software 722 may further be transmitted or received over a network 761 via the system network interface device 708. In an embodiment, the network interface device 708 may operate using microwave coupling, optical coupling, acoustic coupling, or inductive coupling.

While the machine-accessible storage medium 731 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

Thus, embodiments of the present disclosure include systems that include a plasma chamber with a lid assembly that comprises a source assembly and a liner with a monolithic source liner and chamber liner construction, and methods of removing and replacing the lid assembly on the plasma chamber.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

What is claimed is:

1. An apparatus, comprising:
a source assembly with a first surface and a second surface opposite from the first surface; and
a liner coupled to the first surface of the source assembly, wherein the liner comprises:
a first liner over at least a portion of the first surface; and
a second liner that extends away from the first liner, wherein the second liner comprises a ring shape, and wherein the first liner and the second liner are a monolithic structure.

2. The apparatus of claim 1, further comprising:
a temperature control system within the source assembly.

3. The apparatus of claim 2, wherein the temperature control system comprises a heater and/or a cooling channel.

4. The apparatus of claim 2, wherein the temperature control system comprises an inner temperature control system and an outer temperature control system.

5. The apparatus of claim 1, further comprising a plurality of slots along an outer edge of the source assembly.

6. The apparatus of claim 5, wherein each of the plurality of slots are lined by a bushing.

7. The apparatus of claim 1, further comprising a plurality of pins extending up from the second surface of the source assembly.

8. The apparatus of claim 1, further comprising a fixture with a connector over the second surface of the source assembly.

9. The apparatus of claim 1, wherein the liner comprises polysilicon.

10. The apparatus of claim 1, wherein the source assembly is configured to provide RF power or microwave power to a plasma chamber.

11. An apparatus, comprising:
a chamber with an opening; and
a lid assembly configured to seal the opening of the chamber, wherein the lid assembly comprises:
a source assembly; and
a liner, wherein the liner covers a surface of the source assembly and an interior sidewall of the chamber when the lid assembly seals the opening of the chamber.

12. The apparatus of claim 11, further comprising:
a hoist assembly coupled to the chamber, wherein the hoist assembly is configured to displace the lid assembly in a vertical direction.

13. The apparatus of claim 12, wherein the source assembly comprises a fixture with a connector, wherein the hoist assembly is configured to couple with the connector.

14. The apparatus of claim 11, further comprising:
a source guide coupled to the chamber, wherein the source guide is configured to displace the lid assembly laterally.

15. The apparatus of claim 14, wherein the lid assembly comprises a plurality of pins, and wherein the plurality of pins are configured to engage a plurality of holes in the source guide.

16. The apparatus of claim 11, further comprising:
a plurality of pins extending up from the chamber around the opening; and
a plurality of guide holes along an outer edge of the lid assembly, wherein the plurality of pins are configured to engage the plurality of guide holes when the lid assembly seals the opening.

17. The apparatus of claim 16, wherein the plurality of guide holes are each lined by a bushing.

18. An apparatus, comprising:
a metallic source for a plasma chamber; and
a liner coupled to the metallic source, wherein the liner comprises:
a plate portion over the metallic source; and
a ring portion around a perimeter of the plate portion, wherein the ring portion extends from the plate portion away from the metallic source.

19. The apparatus of claim 18, further comprising:
a temperature control system integrated within the metallic source, wherein the temperature control system is configured to control a temperature of the liner.

20. The apparatus of claim 18, wherein the ring portion is configured to be inserted into an interior of the plasma chamber.
